(19) United States
(12) Patent Application Publication
(10) Pub. No.: US 2026/0299427 A1
(43) Pub. Date: Oct. 1, 2026

(54) METHOD FOR MANUFACTURING SEMICONDUCTOR USED RESIST WITH MAGNETIC MATERIALS IN LINE/SPACE PATTERN

(71) Applicant: NANYA TECHNOLOGY CORPORATION, New Taipei City (TW)

(72) Inventor: Chan Hen YANG, New Taipei City (TW)

(21) Appl. No.: 19/095,043

(22) Filed: Mar. 31, 2025

(51) Int. Cl. G03F 7/38; G03F 7/004; G03F 7/09; H10B 12/00

(52) U.S. Cl. CPC G03F 7/38; G03F 7/0043; G03F 7/094; H10B 12/05; H10B 12/315

(57) ABSTRACT

A method for forming a semiconductor device, comprising forming a dielectric layer over a substrate; forming a conductive layer over the dielectric layer; forming a photoresist layer over the conductive layer, wherein the photoresist layer includes a magnetic material; performing an exposure process to the photoresist layer to form an exposed region and an unexposed region in the photoresist layer; applying a directional magnetic field to the photoresist layer; performing a post-exposure baking process to the photoresist layer; performing a developing process to remove portions of the photoresist layer; and transferring a pattern of remaining portions of the photoresist layer to the conductive layer and the dielectric layer.

### BACKGROUND

Inaccurate control during the photolithography can result in poor profiles in the photoresist layer used for patterning, leading to unacceptable variations in line/space. As semiconductor manufacturing processes continue to advance, the negative impact of line/space variations on subsequent processes, measurement, and even yield becomes increasingly significant.

### SUMMARY

One aspect of the present disclosure provides a method for forming a semiconductor device, comprising forming a dielectric layer over a substrate; forming a conductive layer over the dielectric layer; forming a photoresist layer over the conductive layer, wherein the photoresist layer includes a magnetic material; performing an exposure process to the photoresist layer to form an exposed region and an unexposed region in the photoresist layer; applying a directional magnetic field to the photoresist layer; performing a post-exposure baking process to the photoresist layer; performing a developing process to remove portions of the photoresist layer; and transferring a pattern of remaining portions of the photoresist layer to the conductive layer and the dielectric layer.

In some embodiments, the method further comprising: forming a source region and a drain region in the substrate after transferring the pattern of the remaining portions of the photoresist layer to the conductive layer and the dielectric layer.

In some embodiments, the method further comprising: forming a word line electrically coupled with the conductive layer; forming a bit line electrically coupled with the source region; and forming a capacitor electrically coupled with the drain region.

In some embodiments, the photoresist layer comprises a positive photoresist material or a negative photoresist material.

In some embodiments, applying the directional magnetic field to the photoresist layer is performed during the exposure process.

In some embodiments, the method further comprising: applying another directional magnetic field to the photoresist layer during the post-exposure baking process.

In some embodiments, applying the directional magnetic field to the photoresist layer is performed during the post-exposure baking process.

In some embodiments, the directional magnetic field is applied to the photoresist layer along a vertical direction.

In some embodiments, the directional magnetic field is applied to the photoresist layer along a horizontal direction.

In some embodiments, the magnetic material comprises iron (Fe), cobalt (Co), or nickel (Ni).

In some embodiments, the magnetic material in the photoresist layer diffuse downward into a top portion of the conductive layer during the post-exposure baking process.

In some embodiments, a concentration of the magnetic material decreases downward in the top portion of the conductive layer.

In some embodiments, a bottom portion of the conductive layer is free of the magnetic material after the post-exposure baking process is completed.

In some embodiments, the conductive layer is made of polysilicon.

One aspect of the present disclosure provides a memory cell, comprising: a substrate; and a transistor over the substrate and comprising: a source region and a drain region in the substrate; and a gate structure over the substrate and having a dielectric layer and a conductive layer over the dielectric layer, wherein a top portion of the conductive layer includes a magnetic material.

In some embodiments, the memory cell further comprising: a word line electrically coupled with the gate structure; a bit line electrically coupled with the source region; and a capacitor electrically coupled with the drain region.

In some embodiments, the magnetic material comprises iron (Fe), cobalt (Co), or nickel (Ni).

In some embodiments, a concentration of the magnetic material decreases downward in the top portion of the conductive layer.

In some embodiments, a bottom portion of the conductive layer is free of the magnetic material.

In some embodiments, the top portion of the conductive layer is thinner than the bottom portion of the conductive layer.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIGS. 1-7 illustrate cross-sectional views at various stages of forming a semiconductor device in accordance with some embodiments of the present disclosure.

FIGS. 8-12 illustrate cross-sectional views at various stages of forming a semiconductor device in accordance with some embodiments of the present disclosure.

FIG. 13 is a circuit diagram of a memory cell of a memory device in accordance with some embodiments of the present disclosure.

FIGS. 14-18 are cross-sectional views at various stages of forming a memory cell in accordance with some embodiments of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

As used herein, “around”, “about”, “approximately”, or “substantially” may generally mean within 20 percent, or within 10 percent, or within 5 percent of a given value or range. Numerical quantities given herein are approximate meaning that the term “around”, “about”, “approximately”, or “substantially” can be inferred if not expressly stated. One skilled in the art will realize, however, that the values or ranges recited throughout the description are merely examples, and may be reduced or varied with the sown-scaling of the integrated circuits.

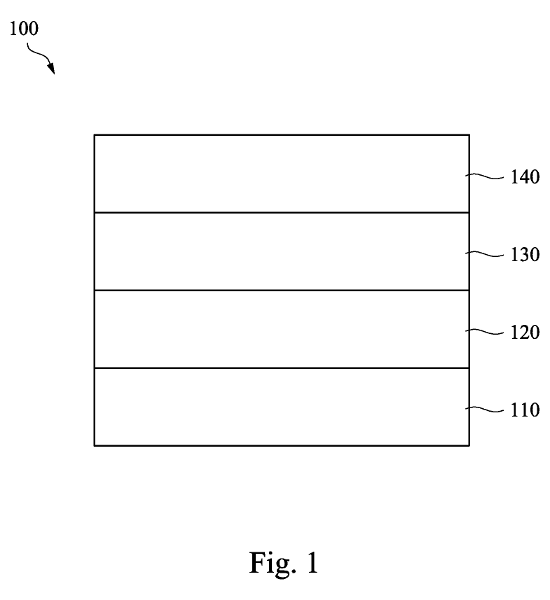

FIGS. 1-7 illustrate cross-sectional views at various stages of forming a semiconductor device in accordance with some embodiments of the present disclosure. In FIG. 1, shown there is a semiconductor device 100. In some embodiments, the semiconductor device 100 may include a dielectric layer 110, a conductive layer 120 over the dielectric layer 110, a hard mask 130 over the conductive layer 120, and a photoresist layer 140 over the hard mask 130. In some embodiments, the dielectric layer 110 may include suitable dielectric material, such as silicon oxide, silicon nitride or the like. In some embodiments, the conductive layer 120 may be formed of, for example, a conductive material such as polycrystalline silicon, polycrystalline silicon germanium, metal nitride, metal silicide, metal oxide, metal, or a combination thereof. In some embodiments, the photoresist layer 140 may include a photoresist material. Photoresist material is a light-sensitive compound extensively employed in semiconductor fabrication. Generally, the photoresist material is made of organic polymers and/or photosensitive compounds, and can be classified into two types: positive photoresists and negative photoresists, with each type responding differently to exposure to light. Positive photoresists become soluble when exposed to a source of light, such as ultraviolet light. Negative photoresists, on the other hand, become less soluble upon exposure to light. In some embodiments, the photoresist layer 140 further includes magnetic materials. In some embodiments, the magnetic materials may include iron (Fe), cobalt (Co), nickel (Ni), or other suitable magnetic materials. In some embodiments, the photoresist layer 140 can be formed by, for example, spreading magnetic metal powder, which includes the magnetic materials, during the deposition of the photoresist layer 140. In some embodiments, the photoresist layer 140 can be formed by, for example, doping the magnetic materials during the deposition of the photoresist layer 140.

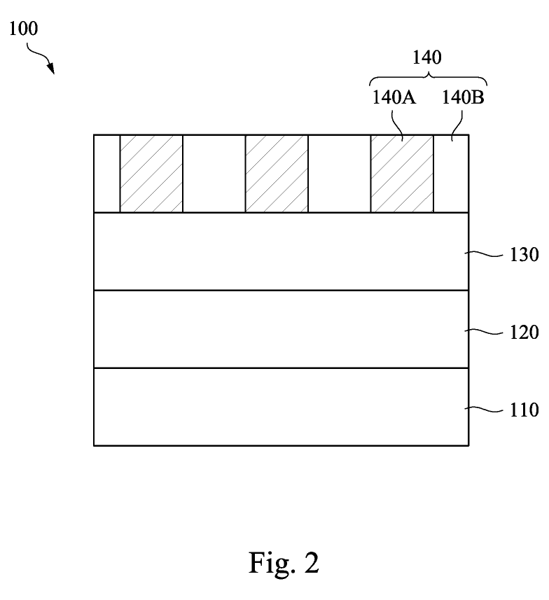

Referring to FIG. 2, an exposure process is performed to pattern the photoresist layer 140 according to a predetermined pattern. As a result, the exposed photoresist layer 140 includes exposed region 140A and unexposed region 140B. As mentioned above, the photoresist layer 140 may comprise a positive photoresist material or a negative photoresist material. Here, negative photoresist material is used as an example of the photoresist layer 140 in the following discussion. However, it should be understand that the photoresist layer 140 may also be positive photoresist material in other embodiments. Accordingly, in the embodiments where the photoresist layer 140 is a negative photoresist material, the exposed region 140A exposed to light becomes insoluble in a developer solution (e.g., organic solution), while the unexposed region 140B becomes soluble therein. Stated another way, the exposed region 140A becomes harder than the unexposed region 140B as a result of the exposure process.

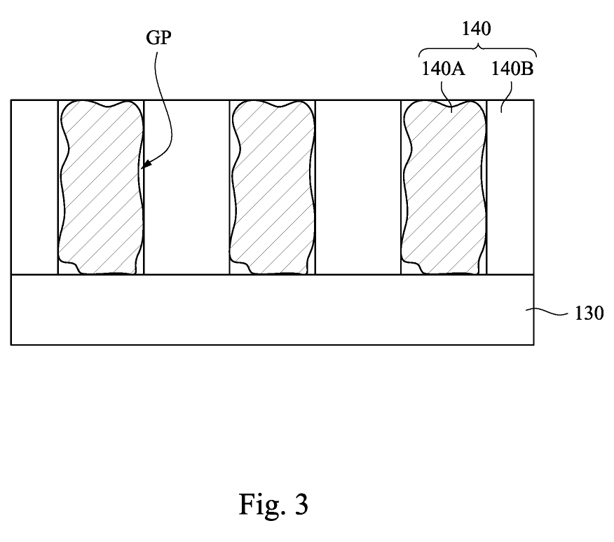

FIG. 3 illustrates an enlarged view portion of the example semiconductor device 100 illustrated in FIG. 2, in accordance with some embodiments of the present disclosure. In some embodiments, due to the physical limitation of exposure process, the exposed region 140A and the unexposed region 140B may include a rough interface. More specifically, one or more gaps GP may be present between the exposed region 140A and the unexposed region 140B. The poor contrast between the exposed region 140A and the unexposed region 140B may result in an unsatisfying lithography performance.

To address the above issue, embodiments of the present disclosure provides a photoresist layer 140 including magnetic materials. Moreover, a directional magnetic field may be applied to the photoresist layer 140 during the exposure process. When the photoresist layer 140 is a negative photoresist, the unexposed region 140B may be softer than the exposed region 140A, and the magnetic field may pull the softer unexposed region 140B toward and filling the gaps GP between the exposed region 140A and the unexposed region 140B. As the exposure process continues, portions of the unexposed region 140B filling the gaps GP may be subject to the exposure process, and such portions become the exposed region 140A. Based on the above discussion, applying a directional magnetic field to the photoresist layer 140 including magnetic materials may be able to smooth the profile of the exposed region 140A of the photoresist layer 140.

In some embodiments, the directional magnetic field may be applied to the photoresist layer 140 during the whole exposure process. In other embodiments, the directional magnetic field may be applied to the photoresist layer 140 once the exposure process has been performed for a period. That it, the exposure process may include a first period and a second period following the first period, in which the second period of the exposure process is performed with the directional magnetic field, while the first period of the exposure process is performed without the directional magnetic field. Accordingly, during the first period, the photoresist layer 140 may undergo the exposure process, which results in the profile of FIG. 3, and the directional magnetic field of the second period starts to repair the rough profile of the exposed region 140A of the photoresist layer 140.

Once the exposure process is complete, a post-exposure baking process may be performed to cure the exposed region 140A of the photoresist layer 140. In some embodiments, another directional magnetic field may be applied to the photoresist layer 140 during the post-exposure baking process, which is also helpful for repairing the rough profile of the exposed region 140A of the photoresist layer 140.

In some embodiments, the directional magnetic field can be applied during the post-exposure baking process, while the directional magnetic field applied during the exposure process can be omitted. In other embodiments, the directional magnetic field can be applied during the exposure process, while the directional magnetic field applied during the post-exposure baking process can be omitted.

In some embodiments, the directional magnetic field may be applied to the photoresist layer 140 along a vertical direction. For example, the directional magnetic field may be applied along a top-to-down direction toward the photoresist layer 140. In other embodiments, the directional magnetic field may be applied to the photoresist layer 140 along a horizontal direction. In such embodiments, the directional magnetic field may be applied along a first horizontal direction to repair one side of the exposed region 140A of the photoresist layer 140, and then be applied along a second horizontal direction opposite to the first horizontal direction to repair another side of the exposed region 140A of the photoresist layer 140.

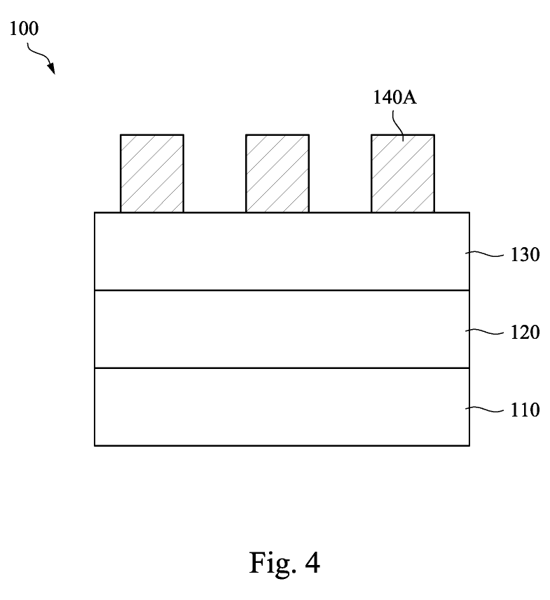

Referring to FIG. 4, a developing process is performed. Thus, the unexposed region 140B dissolves in a developer, while the exposed region 140A remains on the hard mask 130.

In some embodiments, after the developing process, a rinse process is performed to remove any residue and/or particles on the semiconductor device 100. Next, a post-develop bake (PDB) process is performed to ensure the structural stability of the exposed region 140A.

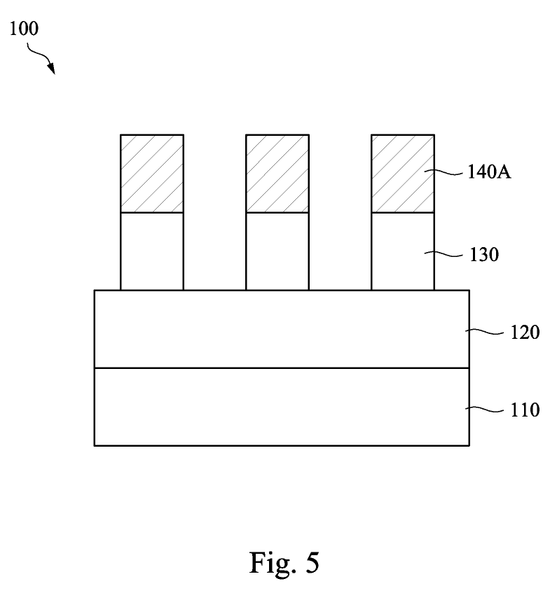

Referring to FIG. 5, an etching process can be performed to remove portions of the hard mask 130 by the exposed region 140A of the photoresist layer 140 as an etch mask. The hard mask 130 may be etched by a suitable etching process, such as an anisotropic dry etching process. In some embodiments, the magnetic material in the photoresist layer 140 can increase the etch resistance to the photoresist layer 140, which is also helpful for patterning the underlying hard mask 130.

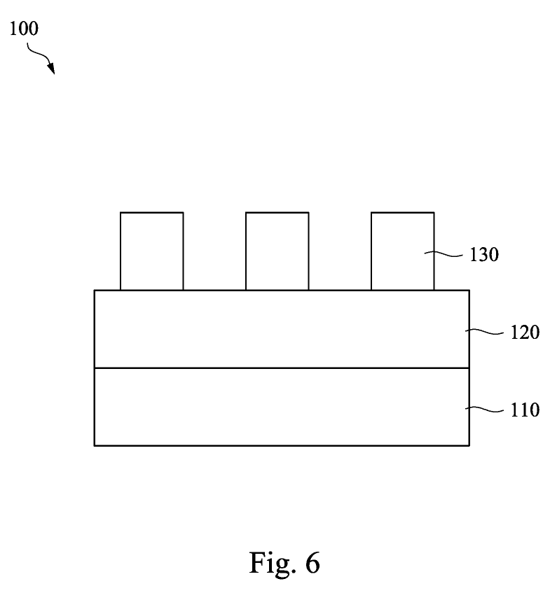

Referring to FIG. 6, after transferring a pattern of the exposed region 140A of the photoresist layer 140 to the hard mask 130, the exposed region 140A of the photoresist layer 140 can be removed.

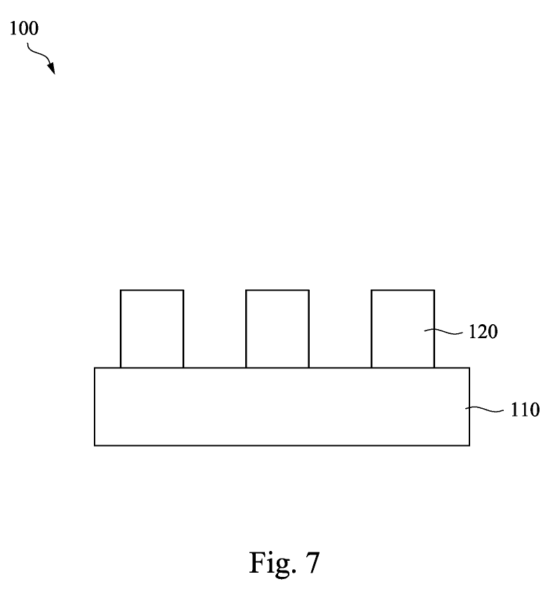

Referring to FIG. 7, the conductive layer 120 can be patterned by using the patterned hard mask 130 as an etch mask. In some embodiments, the conductive layer 120 may be patterned using suitable etching process, such as an anisotropic dry etching process or an isotropic wet etching process. After transferring a pattern of the remaining portions of the hard mask 130 (or the photoresist layer 140) to the conductive layer 120, the hard mask 130 can be removed.

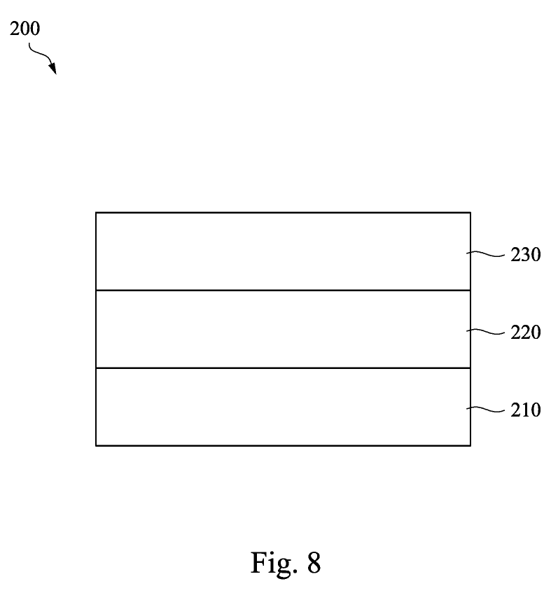

FIGS. 8-12 illustrate cross-sectional views at various stages of forming a semiconductor device in accordance with some embodiments of the present disclosure. In FIG. 8, shown there is a semiconductor device 200. In some embodiments, the semiconductor device 200 may include a dielectric layer 210, a conductive layer 220 over the dielectric layer 110, and a photoresist layer 230 over the conductive layer 220. In some embodiments, the dielectric layer 210 may include suitable dielectric material, such as silicon oxide, silicon nitride or the like. In some embodiments, the conductive layer 120 may be formed of, for example, a conductive material such as polycrystalline silicon, polycrystalline silicon germanium, metal nitride, metal silicide, metal oxide, metal, or a combination thereof. In some embodiments, the material and the manufacturing method of the photoresist layer 230 are similar to those of the photoresist layer 140.

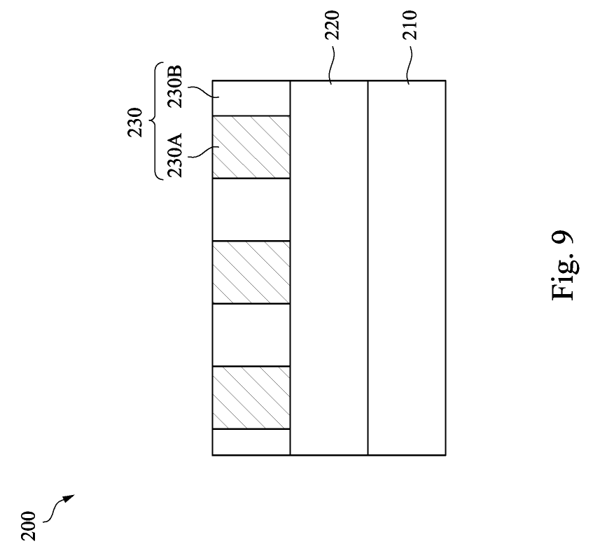

Referring to FIG. 9, an exposure process is performed to pattern the photoresist layer 230 according to a predetermined pattern. As a result, the exposed photoresist layer 230 includes exposed region 230A and unexposed region 230B. As mentioned above, the photoresist layer 230 may comprise a positive photoresist material or a negative photoresist material, similar to the photoresist layer 140. Here, negative photoresist material is used as an example of the photoresist layer 230 in the following discussion. However, it should be understand that the photoresist layer 230 may also be positive photoresist material in other embodiments. Accordingly, in the embodiments where the photoresist layer 230 is a negative photoresist material, the exposed region 230A exposed to light becomes insoluble in a developer solution (e.g., organic solution), while the unexposed region 230B becomes soluble therein.

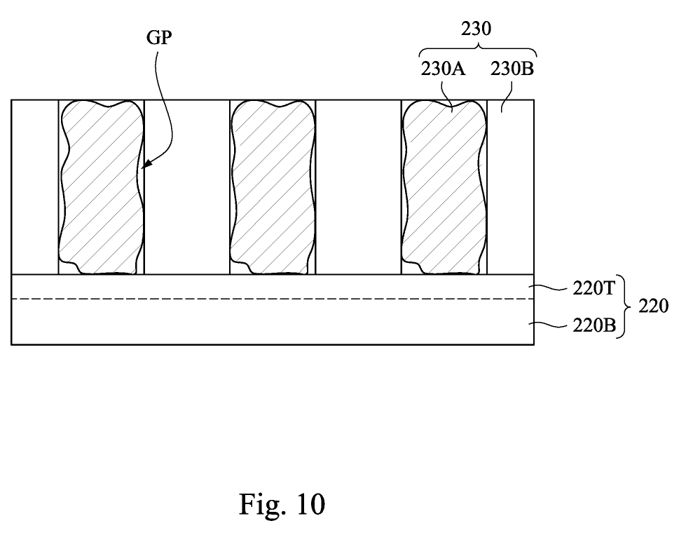

FIG. 10 illustrates an enlarged view portion of the example semiconductor device 200 illustrated in FIG. 9, in accordance with some embodiments of the present disclosure. In some embodiments, due to the physical limitation of exposure process, the exposed region 230A and the unexposed region 230B may include a rough interface. More specifically, one or more gaps GP may be present between the exposed region 230A and the unexposed region 230B. The poor contrast between the exposed region 230A and the unexposed region 230B may result in an unsatisfying lithography performance.

To address the above issue, embodiments of the present disclosure provides a photoresist layer 230 including magnetic materials. Moreover, during the exposure process, applying a directional magnetic field to the photoresist layer 230 including magnetic materials may be able to smooth the profile of the exposed region 230A of the photoresist layer 230 and fill the gaps GP between the exposed region 230A and the unexposed region 230B with the softer unexposed region 230B.

In some embodiments, the directional magnetic field may be applied to the photoresist layer 230 during the whole exposure process. In other embodiments, the directional magnetic field may be applied to the photoresist layer 230 once the exposure process has been performed for a period. That it, the exposure process may include a first period and a second period following the first period, in which the second period of the exposure process is performed with the directional magnetic field, while the first period of the exposure process is performed without the directional magnetic field. Accordingly, during the first period, the photoresist layer 230 may undergo the exposure process, which results in the profile of FIG. 10, and the directional magnetic field of the second period starts to repair the rough profile of the exposed region 230A of the photoresist layer 230.

Once the exposure process is complete, a post-exposure baking process may be performed to cure the exposed region 230A of the photoresist layer 230. In some embodiments, another directional magnetic field may be applied to the photoresist layer 230 during the post-exposure baking process, which is also helpful for repairing the rough profile of the exposed region 230A of the photoresist layer 230.

In some embodiments, the directional magnetic field can be applied during the post-exposure baking process, while the directional magnetic field applied during the exposure process can be omitted. In other embodiments, the directional magnetic field can be applied during the exposure process, while the directional magnetic field applied during the post-exposure baking process can be omitted.

In some embodiments, the directional magnetic field may be applied to the photoresist layer 230 along a vertical direction. In other embodiments, the directional magnetic field may be applied to the photoresist layer 230 along a horizontal direction. In some embodiments, during a thermal process (such as the post-exposure baking process), the magnetic materials in the photoresist layer 230 may diffuse downward into the underlying conductive layer 220. As a result, the top portion 220T of the conductive layer 220 may include some of the materials of the photoresist layer 230, such as magnetic materials of the photoresist layer 230. In some embodiments, the bottom portion 220B of the conductive layer 220 may be free of the materials from the photoresist layer 230. In some embodiments, the concentration of the magnetic materials may decrease downward in the top portion 220T of the conductive layer 220. In some embodiments, the top portion 220T of the conductive layer 220 may be thinner than the bottom portion 220B of the conductive layer 220.

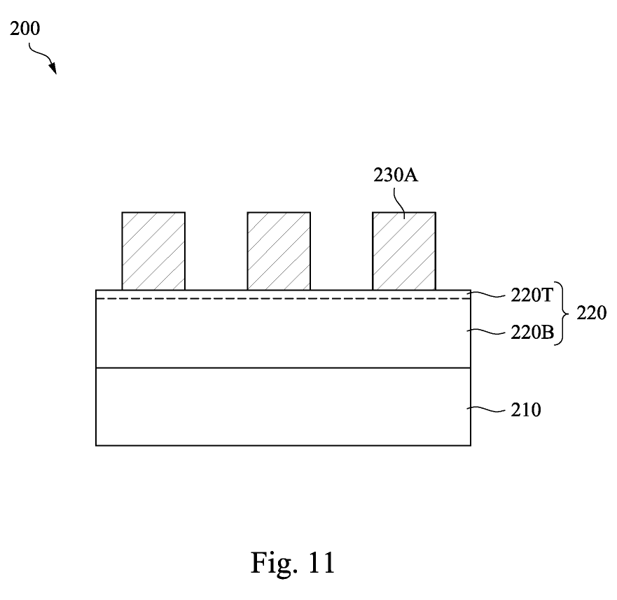

Referring to FIG. 11, a developing process is performed. Thus, the unexposed region 230B of the photoresist layer 230 dissolves in a developer, while the exposed region 230A remains on the conductive layer 220.

In some embodiments, after the developing process, a rinse process is performed to remove any residue and/or particles on the semiconductor device 200. Next, a post-develop bake (PDB) process is performed to ensure the structural stability of the exposed region 230A.

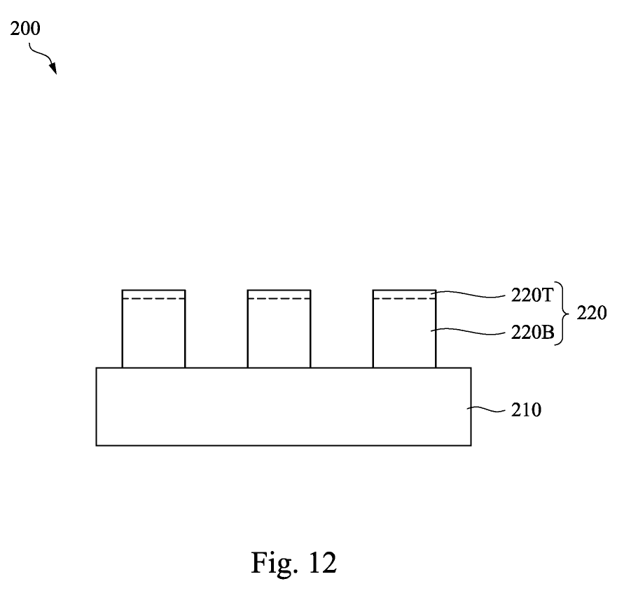

Referring to FIG. 12, an etching process can be performed to remove portions of the conductive layer 220 by the exposed region 230A of the photoresist layer 230 as an etch mask. The conductive layer 220 may be etched by a suitable etching process, such as an anisotropic dry etching process or an isotropic wet etching process. In some embodiments, the magnetic material in the photoresist layer 230 can increase the etch resistance to the photoresist layer 230, which is also helpful for patterning the underlying conductive layer 220. After transferring a pattern of the exposed region 230A of the photoresist layer 230 to the conductive layer 220, the exposed region 230A can be removed.

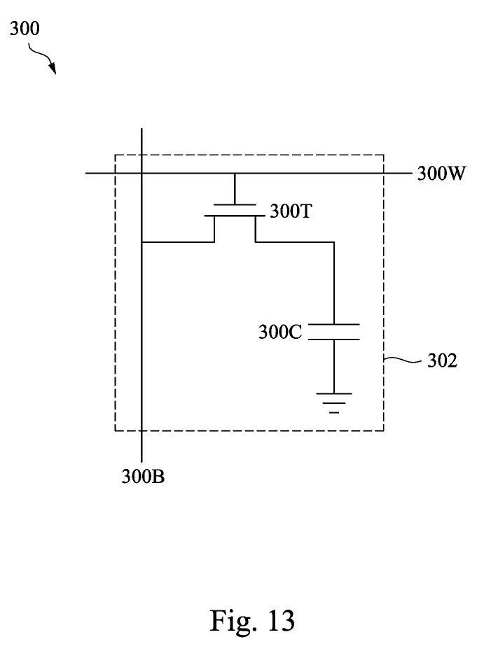

FIG. 13 is a circuit diagram of a memory cell of a memory device in accordance with some embodiments of the present disclosure. With reference to FIG. 13, a memory device 300 consists of multiple memory cells 302 arranged in a rectangular matrix configuration. In some embodiments, the memory device 300 is a dynamic random access memory (DRAM) device. The memory cell 302 of the memory device 300 consists of a transistor 300T and a capacitor 300C electrically connected to the transistor 300T as main structures. The one side of capacitor 300C is coupled with the drain region of the transistor 300T and the other side of the capacitor 300C is coupled to the ground. The memory device 300 further includes a word line 300W coupled with the gate region of the transistor 300T, and a bit line 300B coupled with the source of the transistor 300T.

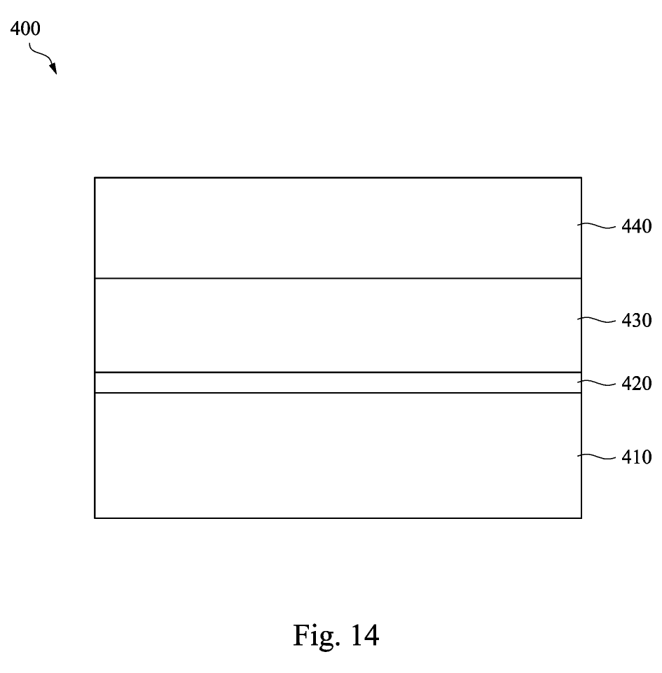

FIGS. 14-18 are cross-sectional views at various stages of forming a memory cell in accordance with some embodiments of the present disclosure. As shown in FIG. 14, a memory cell 400 may include a substrate 410. a gate dielectric layer 420 over the substrate 410, a gate conductive layer 430 over the gate dielectric layer 420, and a photoresist layer 440 over the gate conductive layer 430. In some embodiments, the gate dielectric layer 420 may include suitable dielectric material, such as silicon oxide, silicon nitride or the like. In some embodiments, the conductive layer 120 may be formed of, for example, a conductive material such as polycrystalline silicon, polycrystalline silicon germanium, metal nitride, metal silicide, metal oxide, metal, or a combination thereof. In some embodiments, the material and the manufacturing method of the photoresist layer 440 are similar to those of the photoresist layer 140.

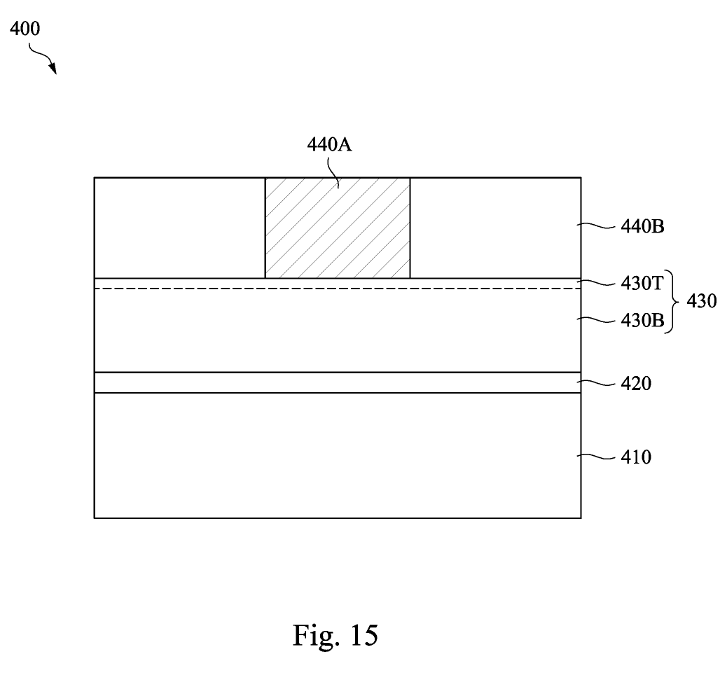

Referring to FIG. 15, an exposure process is performed to pattern the photoresist layer 440 according to a predetermined pattern. As a result, the photoresist layer 440 includes exposed region 440A and unexposed region 440B. As mentioned above, the photoresist layer 440 may comprise a positive photoresist material or a negative photoresist material, similar to the photoresist layer 140. Here, negative photoresist material is used as an example of the photoresist layer 440 in the following discussion. However, it should be understand that the photoresist layer 440 may also be positive photoresist material in other embodiments. Accordingly, in the embodiments where the photoresist layer 440 is a negative photoresist material, the exposed region 440A exposed to light becomes insoluble in a developer solution (e.g., organic solution), while the unexposed region 440B becomes soluble therein.

In some embodiments, due to the physical limitation of exposure process, the exposed region 440A and the unexposed region 440B may include a rough interface. More specifically, one or more gaps (not shown in FIG. 15) may be present between the exposed region 440A and the unexposed region 440B. The poor contrast between the exposed region 440A and the unexposed region 440B may result in an unsatisfying lithography performance.

To address the above issue, embodiments of the present disclosure provides a photoresist layer 440 including magnetic materials. Moreover, during the exposure process, applying a directional magnetic field to the photoresist layer 440 including magnetic materials may be able to smooth the profile of the exposed region 440A of the photoresist layer 440 and fill the gaps between the exposed region 440A and the unexposed region 440B with the softer unexposed region 440B.

In some embodiments, the directional magnetic field may be applied to the photoresist layer 440 during the whole exposure process. In other embodiments, the directional magnetic field may be applied to the photoresist layer 440 once the exposure process has been performed for a period. That it, the exposure process may include a first period and a second period following the first period, in which the second period of the exposure process is performed with the directional magnetic field, while the first period of the exposure process is performed without the directional magnetic field. Accordingly, during the first period, the photoresist layer 440 may undergo the exposure process, which results in the rough profile of the exposed region 440A and the unexposed region 440B, and the directional magnetic field of the second period starts to repair the rough profile of the exposed region 440A of the photoresist layer 440.

Once the exposure process is complete, a post-exposure baking process may be performed to cure the exposed region 440A of the photoresist layer 440. In some embodiments, another directional magnetic field may be applied to the photoresist layer 440 during the post-exposure baking process, which is also helpful for repairing the rough profile of the exposed region 440A.

In some embodiments, the directional magnetic field can be applied during the post-exposure baking process, while the directional magnetic field applied during the exposure process can be omitted. In other embodiments, the directional magnetic field can be applied during the exposure process, while the directional magnetic field applied during the post-exposure baking process can be omitted.

In some embodiments, the directional magnetic field may be applied to the photoresist layer 440 along a vertical direction or a horizontal direction.

In some embodiments, during a thermal process (such as the post-exposure baking process), the magnetic materials in the photoresist layer 440 may diffuse downward into the underlying gate conductive layer 430. As a result, the top portion 430T of the gate conductive layer 430 may include some of the materials of the photoresist layer 440, such as the magnetic materials of the photoresist layer 440. In some embodiments, the bottom portion 430B of the gate conductive layer 430 may be free of the magnetic materials from the photoresist layer 440. In some embodiments, the concentration of the magnetic materials may decrease downward in the top portion 430T of the gate conductive layer 430. In some embodiments, the top portion 430T of the gate conductive layer 430 may be thinner than the bottom portion 430B of the gate conductive layer 430.

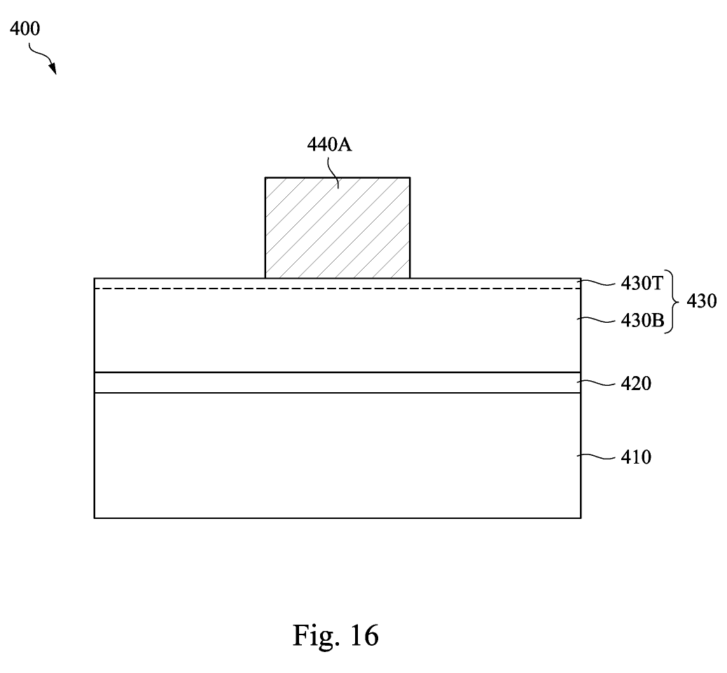

Referring to FIG. 16, a developing process is performed. Thus, the unexposed region 440B of the photoresist layer 440 dissolves in a developer, while the exposed region 440A remains on the gate conductive layer 430.

In some embodiments, after the developing process, a rinse process is performed to remove any residue and/or particles on the memory cell 400. Next, a post-develop bake (PDB) process is performed to ensure the structural stability of the exposed region 440A.

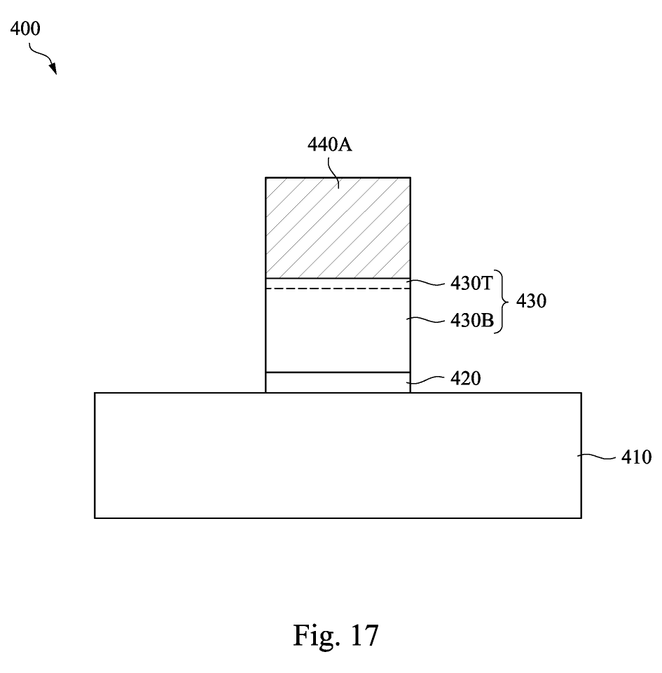

Referring to FIG. 17, an etching process can be performed to remove portions of the gate conductive layer 430 and the gate dielectric layer 420 by the exposed region 440A as an etch mask. In some embodiments, the patterned gate conductive layer 430 and the patterned gate dielectric layer 420 can be collectively referred to as a gate structure GS. The gate conductive layer 430 and the gate dielectric layer 420 may be etched by a suitable etching process, such as an anisotropic dry etching process or an isotropic wet etching process. In some embodiments, the magnetic material in the photoresist layer 440 can increase the etch resistance to the photoresist layer 440, which is also helpful for patterning the underlying gate conductive layer 430 and the gate dielectric layer 420. After transferring a pattern of the exposed region 440A of the photoresist layer 440 to the gate conductive layer 430 and the gate dielectric layer 420, the exposed region 440A can be removed.

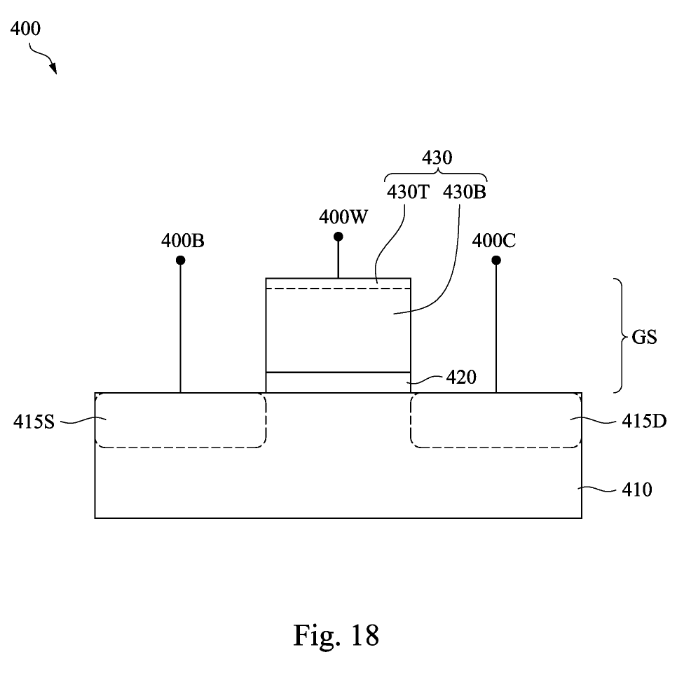

Referring to FIG. 18, a source region 410S and a drain region 410D are formed in the substrate 410 and an opposite sides of the gate structure GS. In some embodiments, the substrate 410 (e.g., channel region), the gate structure GS, and the source region 410S and the drain region 410D can function as a transistor of the memory cell 400. Then, a word line 400W is formed electrically coupled with the gate structure GS, a bit line 200B is formed electrically coupled with the source region 410S, and a capacitor 400C is formed electrically coupled with the drain region 410D. In some embodiments, the equivalent circuit diagram of the memory cell 400 shown in FIG. 18 may be similar to the memory cell 300 as discussed in FIG. 13.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A method for forming a semiconductor device, comprising:
forming a dielectric layer over a substrate;
forming a conductive layer over the dielectric layer;
forming a photoresist layer over the conductive layer, wherein the photoresist layer includes a magnetic material;
performing an exposure process to the photoresist layer to form an exposed region and an unexposed region in the photoresist layer;
applying a directional magnetic field to the photoresist layer;
performing a post-exposure baking process to the photoresist layer;
performing a developing process to remove portions of the photoresist layer; and
transferring a pattern of remaining portions of the photoresist layer to the conductive layer and the dielectric layer.

2. The method of claim 1, further comprising:
forming a source region and a drain region in the substrate after transferring the pattern of the remaining portions of the photoresist layer to the conductive layer and the dielectric layer.

3. The method of claim 2, further comprising:
forming a word line electrically coupled with the conductive layer;
forming a bit line electrically coupled with the source region; and
forming a capacitor electrically coupled with the drain region.

4. The method of claim 1, wherein the photoresist layer comprises a positive photoresist material or a negative photoresist material.

5. The method of claim 1, wherein applying the directional magnetic field to the photoresist layer is performed during the exposure process.

6. The method of claim 5, further comprising:
applying another directional magnetic field to the photoresist layer during the post-exposure baking process.

7. The method of claim 1, wherein applying the directional magnetic field to the photoresist layer is performed during the post-exposure baking process.

8. The method of claim 1, wherein the directional magnetic field is applied to the photoresist layer along a vertical direction.

9. The method of claim 1, wherein the directional magnetic field is applied to the photoresist layer along a horizontal direction.

10. The method of claim 1, wherein the magnetic material comprises iron (Fe), cobalt (Co), or nickel (Ni).

11. The method of claim 1, wherein the magnetic material in the photoresist layer diffuse downward into a top portion of the conductive layer during the post-exposure baking process.

12. The method of claim 11, wherein a concentration of the magnetic material decreases downward in the top portion of the conductive layer.

13. The method of claim 11, wherein a bottom portion of the conductive layer is free of the magnetic material after the post-exposure baking process is completed.

14. The method of claim 11, wherein the conductive layer is made of polysilicon.

15. A memory cell, comprising:
a substrate; and
a transistor over the substrate and comprising:
a source region and a drain region in the substrate; and
a gate structure over the substrate and having a dielectric layer and a conductive layer over the dielectric layer, wherein a top portion of the conductive layer includes a magnetic material.

16. The memory cell of claim 15, further comprising:
a word line electrically coupled with the gate structure;
a bit line electrically coupled with the source region; and
a capacitor electrically coupled with the drain region.

17. The memory cell of claim 15, wherein the magnetic material comprises iron (Fe), cobalt (Co), or nickel (Ni).

18. The memory cell of claim 15, wherein a concentration of the magnetic material decreases downward in the top portion of the conductive layer.

19. The memory cell of claim 15, wherein a bottom portion of the conductive layer is free of the magnetic material.

20. The memory cell of claim 19, wherein the top portion of the conductive layer is thinner than the bottom portion of the conductive layer.
